(19) United States
(12) Patent Application Publication
(10) Pub. No.: US 2008/0285239 A1
(43) Pub. Date: Nov. 20, 2008

(54) Ic Holder

(76) Inventor: Dong-Goo Yun, Seoul (KR)

Correspondence Address: CANTOR COLBURN, LLP, 20 Church Street, 22nd Floor, Hartford, CT, 06103, US

(21) Appl. No.: 12/094,705

(22) PCT Filed: Nov. 24, 2006
(86) PCT No.: PCT/KR06/04965

§ 371 Date: May 22, 2008

(30) Foreign Application Priority Data
Nov. 25, 2005 (KR) 10-2005-0113825
Nov. 30, 2005 (KR) 10-2005-0115988
Jan. 18, 2006 (KR) 10-2006-0005583
Feb. 7, 2006 (KR) 10-2006-0011841
Sep. 13, 2006 (KR) 10-2006-0088569

(51) Int. Cl. H05K 7/20; H05K 1/00

(52) U.S. Cl. 361/720; 439/78

(57) ABSTRACT

Provided is an integrated circuit (IC) holder that includes: a case into which an IC package is inserted; a fastening unit for fastening the case to a printed circuit board (PCB); and a heat-dissipation unit for transferring heat generated from the IC package to the case, so that the IC holder is not in contact with the PCB or designed to avoid devices or circuits adjacent to the IC package even though it is contact with the PCB, thereby reducing an unnecessary area not used for layout of the PCB and providing a layout structure similar to that using only the IC package. Further, the IC holder can have a solderless structure to make the devices be readily replaced, solve an environment problem, and be easily applied to various kinds of the IC packages.

### TECHNICAL FIELD

The present invention relates to an integrated circuit (IC) holder, and more particularly, to an IC holder capable of substituting for a socket.

### BACKGROUND ART

A semiconductor integrated circuit (hereinafter, referred to as an “IC”) has been steadily developed to achieve high-density integration and designed to operate at a high-speed operating frequency. The higher the integration density and the operation speed of the IC are, the more the IC radiates heat.

In the past, an IC package has been directly mounted on a printed circuit board (PCB) through soldering, but at present the IC package is generally inserted into a corresponding-size socket soldered to the PCB.

Using the socket, the IC can be readily replaced when it is defective, and recycled by picking it up from obsolete equipment.

However, the socket is relatively larger than the IC package, so that it is difficult to place peripheral devices adjacent to the IC package on the PCB. Further, various kinds of sockets are needed corresponding to diverse shapes of the IC package.

As an example of the socket, there is a ball grid array (BGA) socket in which a pin with a built-in spring is in contact with a ball used as an external connection terminal of a BGA type IC package. In this case, predetermined pressure should be applied to each pin, and thus the pressure applied to a part of the PCB where the socket is mounted becomes higher as more balls are provided in the IC package. Accordingly, the socket unnecessarily stresses the IC package and the PCB, and the strength of the PCB decreases and noise is made while the IC package operates at high speed because the IC package is mounted on the PCB through the long pin of the socket instead of the short ball of the IC package.

### DISCLOSURE OF INVENTION

### Technical Problem

In order to solve the above problems, the present invention provides an IC holder capable of substituting for a socket.

### Technical Solution

According to an aspect of the present invention, an integrated circuit (IC) holder comprises: a case into which an IC package is inserted; a fastening unit for fastening the case to a printed circuit board (PCB); and a heat-dissipation unit for transferring heat from the IC package to the case.

According to another aspect of the present invention, an IC holder comprises: four case bodies for fastening a corner of an IC package; a first fastening unit for fastening the case bodies to a PCB; a case cover placed on the case bodies and pressing the IC package to make an external connection terminal of the IC package contact an electric pattern of the PCB; a heat-dissipation unit for transferring heat from the IC package to the case cover; and a second fastening unit for fastening the case cover to the case bodies.

### Advantageous Effects

Accordingly, an IC holder according to an exemplary embodiment of the present invention is capable of substituting for a socket because a case capable of holding an IC package is fastened and pressured to a PCB by a fastening unit such as a screw or the like such that an external connection terminal of the IC package is in direct contact with the PCB. Further, the IC holder does not contact the PCB or otherwise is designed to avoid neighboring devices or circuit parts, so that placing parts or routing of the PCB pattern can be more freely designed.

Further, the IC holder contacts a large area of the IC package through a heat-dissipation unit such as a heat conductive tape or the like, thereby effectively dissipating heat. Also, devices can be readily replaced by solderless assembly, thereby solving environmental problems.

Also, an external connection terminal of the IC package is in direct contact with the PCB, so that the IC package can smoothly operate at high speed. Further, the IC package is covered with a metal holder, thereby preventing electromagnetic waves from radiating from the IC package.

Further, the IC holder can be used regardless of the kinds of IC packages such as BGA, PLCC, QFP type IC packages. Thus, the production cost is reduced. Also, the IC holder can be variously applied regardless of the number of external connection terminals of the IC package or the size of the IC package within an allowable limit.

### BRIEF DESCRIPTION OF THE DRAWINGS

These and/or other aspects and advantages of the present invention will become apparent and more readily appreciated from the following description of the embodiments, taken in conjunction with the accompanying drawings of which:

FIG. 1 is a perspective view of an integrated circuit (IC) holder according to an exemplary embodiment of the present invention;

FIG. 2 is a cross-sectional view of the IC holder of FIG. 1;

FIG. 3 is an exploded perspective view of an IC holder according to another exemplary embodiment of the present invention; and

FIG. 4 is an exploded perspective view of an IC holder according to still another exemplary embodiment of the present invention.

### MODE FOR THE INVENTION

The present invention will now be described more fully hereinafter with reference to attached drawings, wherein the same numerals denote the same components.

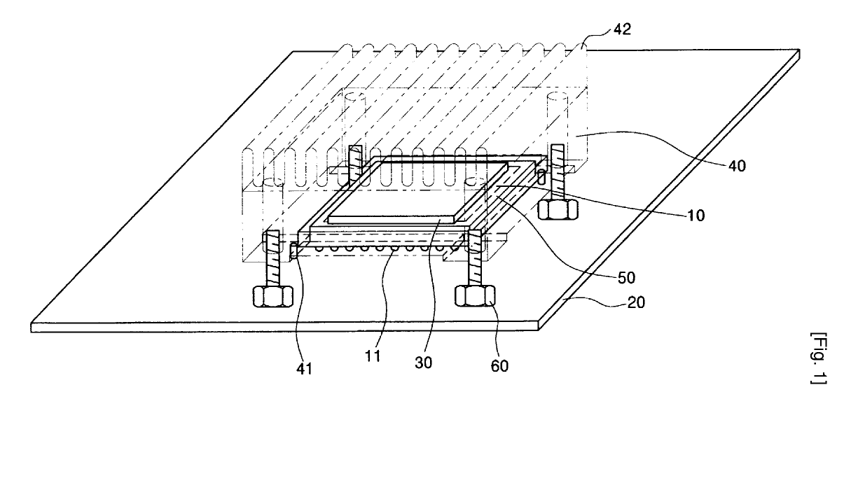

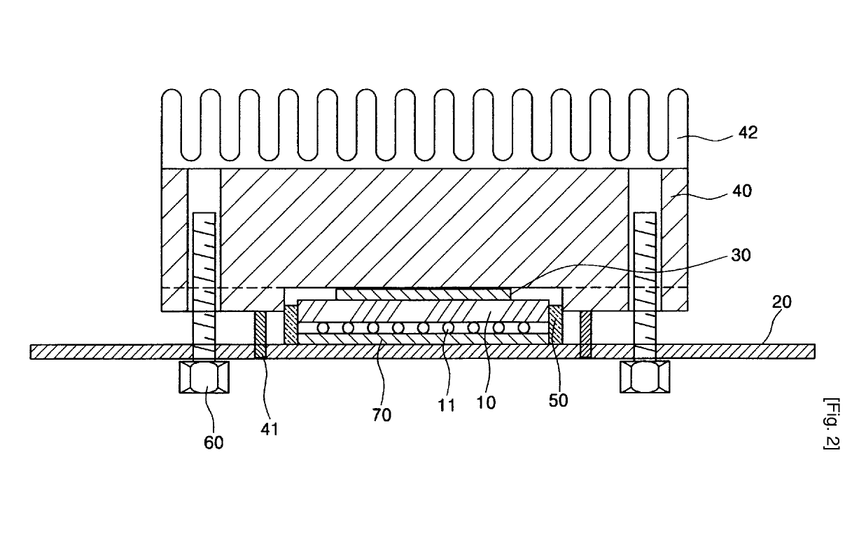

FIGS. 1 and 2 are a perspective view and a cross-sectional view of an integrated circuit (IC) holder according to an exemplary embodiment of the present invention, respectively.

The IC holder includes a case 40 for holding an IC package 10, a screw 60 as a fastening unit for fastening the case 40 to a PCB 20, and a heat-conductive tape 30 as a heat-dissipation and adhesion unit for transferring heat generated from the IC package 10 to the case 40 and making the IC package 10 closely contact the case 40.

The heat-conductive tape 30 is interposed between the IC package 10 and the case 40, and closely contacts both the IC package 10 and the case 40, thereby transferring heat from the IC package 10 to the case 40. Further, the heat-conductive tape 30 is made of a resilient material and uniformly distributes pressure applied to an upper surface of the IC package 10 even though each screw 60 pulls the case 40 with non-uniform force as the screw 60 does not precisely fasten the case 40 to the PCB 20 by a tool such as a torque wrench.

In the above-described embodiment, the heat-conductive tape 30 is preferably used as the heat-dissipation and adhesion unit, but not limited thereto. Alternatively, a heat-conductive adhesive agent, a heat-conductive grease, and other good heat-conductive materials may be employed as the heat-dissipation and adhesion unit.

The case 40 includes screw holes and is coupled to the PCB 20 by the screws 60. Further, the case 40 includes a guide pin 41 to be inserted into the PCB 20, thereby maximally decreasing movement of the case 40 due to tolerance between the screw 60 and the screw holes. Also, the case 40 has a groove on a bottom thereof corresponding to the size of the IC package 10, thereby holding the IC package 10.

Meanwhile, the bottom of the case 40 has a gap at a predetermined height in all directions so as to correspond to an IC package 10 having a lead-shaped external connection terminal 11 such as a plastic lead chip carrier (PLCC) or quad flat package (QFP) type IC package as well as a BGA type IC package.

When the IC package 10 is the PLCC or QFP type, the lead (i.e., the external connection terminal 11 of the IC package 10) closely contacts the PCB 20 by pressure applied between the case 40 and the PCB 20 with the screw 60 in the state that the gap in all directions is filled with an elastic-insulating material such as rubber or the like.

In addition, the case 40 is provided with a heat sink 42 on an upper surface thereof, thereby efficiently dissipating heat transferred from the IC package 10 to the case 40 through the heat-conductive tape 30. In this embodiment, the heat sink 42 is provided separately from the case 40, but not limited thereto. Alternatively, the heat sink 42 and the case 40 may be formed as a single body.

The IC package 10 transmits and receives a signal through the external connection terminal 11.

The PCB 20 has an electric pattern to contact the external connection terminal 11 of the IC package 10, and thus the external connection terminal 11 of the IC package 10 can contact the electric pattern of the PCB 20 directly or via an electric conductive sheet 70 (refer to FIG. 2).

Further, the PCB 20 includes screw holes to be coupled with the case 40 by the screw 60. Also, the PCB 20 includes a guide hole into which the guide pin 41 of the case 40 is inserted, thereby maximally decreasing the movement of the case 40 owing to the tolerance between the screw 60 and the screw hole.

In the IC holder as shown in FIGS. 1 and 2, the PCB 20 and the case 40 are coupled and pressed by the screw 60, so that the case 40 having the groove to hold the IC package 10 makes the external connection terminal 11 of the IC package 10 contact the electric pattern of the PCB 20.

In the meantime, the case 40 is provided with a groove corresponding to the size of the IC package 10. Therefore, there is a problem in that the case 40 should be provided variously corresponding to diverse kinds of the IC package 10. To solve this problem, if the IC package 10 is smaller than the groove of the case 40 within an allowable limit, a guide panel 50 is additionally provided in an inner wall of the case 40 to thereby hold the IC package 10.

As shown in FIG. 2, the case 40 is preferably not in contact with the PCB 20, so that the PCB 20 can have the electric pattern even under the case 40. Alternatively, an insulating material (not shown) may be additionally provided on the bottom of the case 40 such that the operation of the PCB is not affected by contact between the case 40 and the PCB 20.

When the case 40 is made of metal, the case 40 can not only prevent electromagnetic waves from radiating from the IC package 10 to the outside but also prevent the IC package 10 from malfunction due to external electromagnetic waves.

Referring to FIG. 2, the IC holder additionally includes the electric conductive sheet 70 between the external connection terminal 11 of the IC package 10 and the PCB 20, thereby facilitating the contact between the external connection terminal 11 of the IC package 10 and the electric pattern of the PCB 20.

For example, the electric conductive sheet 70 is exemplarily disclosed in U.S. Pat. No. 6,452,479, in which electrical connection is performed in a partial surface of the sheet where the pressure is applied.

When the pressure is applied to the electric conductive sheet 70 via the ball 11 (i.e., the external connection terminal) of the IC package 10 by the fastening of the screw 60, the part of the electric conductive sheet 70 receiving the pressure becomes conductive so that the electric conductive sheet 70 electrically connects the PCB 20 and the ball 11. On the other hand, a part of the electric conductive sheet 70 where the pressure is not applied maintains a nonconductive state. Because the electric conductive sheet 70 does not need an electric pattern such that it can be easily used. Further, the elasticity of the electric conductive sheet 70 causes the pressure to be uniformly applied from the external connection terminal 11 to the PCB 20.

Accordingly, the electric conductive sheet 70 can secure more stable electric contact.

In the foregoing embodiment, the IC package 10 includes the ball-shaped external connection terminal 11, but not limited thereto. Alternatively, the present invention may be applied to the IC package including a lead-shaped external connection terminal. Further, the case 40 and the PCB 20 are coupled by the screw 60, but not limited thereto. Alternatively, any unit can be used for fastening the case 40 to the PCB 20 as long as it can apply a predetermined pressure.

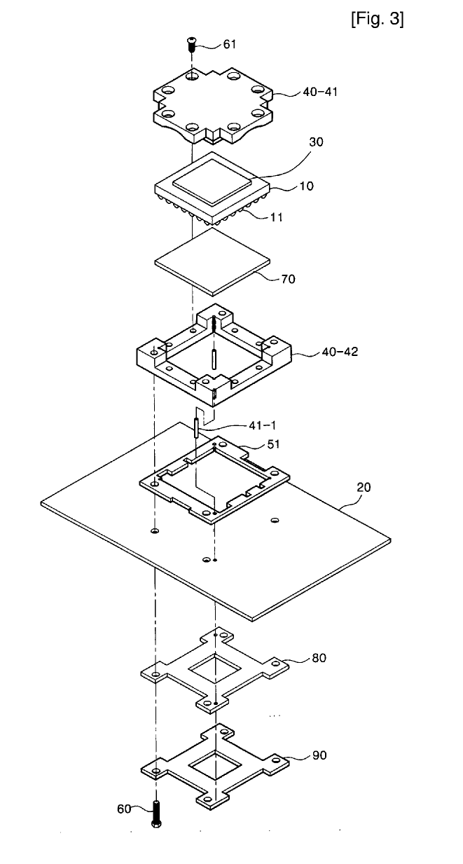

FIG. 3 is an exploded perspective view of an IC holder according to another exemplary embodiment of the present invention. In the IC holder illustrated in FIG. 1 the screw 60 allows the bottom of the case 40 accommodating the IC package 10 not to come into direct contact with the PCB 20, but FIG. 3 illustrates that a guide panel 51 functioning as an insulator is placed on the PCB 20 and a case body 40-42 is put on the guide panel 51. Thus, the guide panel 51 directly contacts the PCB 20. The guide panel 51 is designed to correspond to layout patterns or various devices on the PCB 20, so that the guide panel 51 is in direct contact with the PCB 20 without interfering the devices or the layout pattern.

The guide panel 51 internally has a rectangular space into which the electric conductive sheet 70 and the IC package 10 are inserted in sequence. Then, the heat-dissipation and adhesion unit 30 such as the heat-conductive tape 30 is put on an upper surface of the IC package 10, and a case cover 40-41 is fastened to the case body 40-42 by a screw 61.

A guide pin 41-1 inserted into the case body 40-42 penetrates holes of the insulator (guide panel) 51 and the PCB, and protrudes a little over the bottom of the PCB 20. The guide pin 41-1 maximally decreases the movement of the case body 40-42, the guide panel 51 and the PCB 20 due to the tolerance of the screw hole. Substantially, inserting the guide pin 41 into the hole of the case body 40-42 is convenient rather than applying the guide pin 41 of FIG. 1 to the case body 40-42. Alternatively, the guide pin 41 may be used as shown in FIG. 1.

In the IC holder, the guide pin 41-1 protruding over the bottom of the PCB 20 is inserted into the guide hole of an insulating body 80, and a supporter 90 is further provided under the insulating body 80. Further, the supporter 90 and the case body 40-42 are fastened by the screw 60.

In the IC holder shown in FIG. 3, the thickness of the guide panel 51 that functions as an insulator approximates to the thickness sum of the electric conductive sheet 70 and the IC package 10, so that the internal rectangular space of the guide panel 51 allows the electric conductive sheet 70 and the IC package 10 to be precisely aligned with the electric pattern of the PCB 20 through the guide pin 41-1. Further, even though the IC package 10 is smaller than an internal rectangular space of the case body 40-42, it is enough if only the guide panel 51 corresponds to an outline of the IC package 10.

If the IC package 10 is directly soldered to the PCB 20, some devices are generally placed adjacent to the IC package 10. The guide panel 51 according to an exemplary embodiment of the present invention can be prepared in the stage of completing the placing and routing of the PCB 20 while avoiding adjacent devices as shown in FIG. 3, thereby providing a structure similar to that having only the IC package 10.

As necessary, a heat sink or a fan may be additionally attached to an upper surface of the case cover 40-41 of FIG. 3, thereby dissipating heat. In this case, a screw hole formed in a corner part of the case body 40-42 may be used as a screw hole for fastening the heat sink or the fan.

The supporter 90 is used along with the insulator 80 having approximately the same shape. The PCB 20 may be deformed when the pressure is applied downward by the screw 60 from the case cover 40-41 to the IC package 10. If the PCB 20 is deformed, the electrical contact is not abnormally performed between the electric pattern of the PCB 20 and the external connection terminal of the IC package 10. Accordingly, the supporter 90 is used for preventing the PCB 20 from deformation due to the pressure.

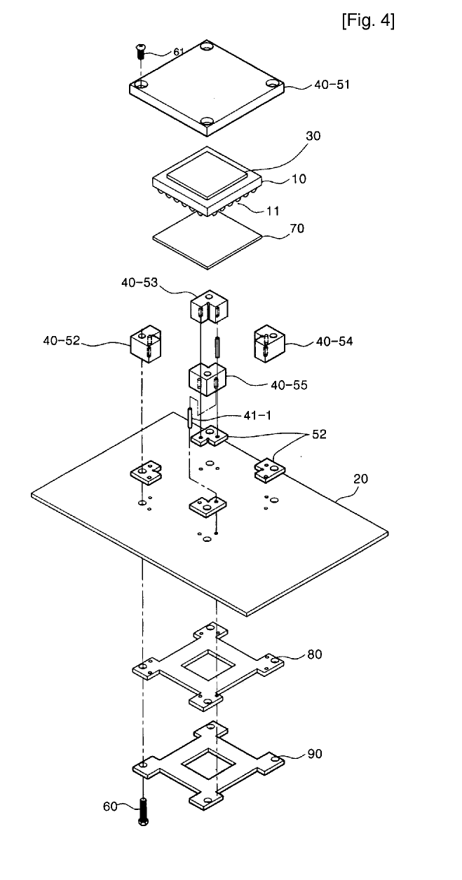

FIG. 4 is an exploded perspective view illustrating that case bodies 40-52, 40-53, 40-54 and 40-55 are formed with holes in which guide pins 41-1 can be inserted into left and right sides thereof about a screw hole, unlike the case body 40-42 of FIG. 3.

In FIG. 3, various guide panels 51 are needed to avoid the devices adjacent to the IC package 10 according to diverse layouts, but in FIG. 4, insulating pads 52 having the same shape as the bottom surfaces of the case bodies 40-52, 40-53, 40-54 and 40-55 can be standard-applied to the diverse layouts. Further, an inner corner of each case bodies 40-52, 40-53, 40-54 and 40-55 functions to precisely align the electric conductive sheet 70 with the IC package 10, so that the guide panel 52 may be smaller than the thickness of the guide panel 51 of FIG. 3. Also, in the case where the case bodies 40-52, 40-53, 40-54 and 40-55 are made of not metal but insulating material, the insulating pads 52 are not needed. In other words, the insulating pad 52 of FIG. 4 serves as only an insulator between the PCB 20 and the case bodies 40-52, 40-53, 40-54 and 40-55, so that the insulating pad 52 is not needed if the case bodies 40-52, 40-53, 40-54 and 40-55 are made of an insulating material.

The case bodies 40-52, 40-53, 40-54 and 40-55 of FIG. 4 can be applied to a large-sized IC package as well as a small-sized IC package. However, if the IC package 10 is relatively large, the thickness of the case cover 40-51 should increase in proportion as a distance between the screw holes becomes longer, as compared with that of FIG. 3. Nevertheless, the case bodies 40-52, 40-53, 40-54 and 40-55 have a very simple structure, so that it is possible to carry out mass and low cost production based on extrusion moulding.

Like the case cover of FIG. 3, as necessary, a heat sink or a fan may be additionally attached to an upper surface of the case cover 40-51 of FIG. 4, thereby dissipating heat.

When the IC holder is assembled, the case bodies 40-52, 40-53, 40-54 and 40-55 are fastened to the PCB 20 by the screw 60, and then the electric conductive sheet 70 and the IC package 10 are put in the case bodies 40-52, 40-53, 40-54 and 40-55 in sequence. Then, the heat-dissipation and adhesion unit such as the heat conductive tape 30 is put on the upper surface of the IC package 10, and then the case cover 40-51 is fastened to the case bodies 40-52, 40-53, 40-54 and 40-55 by the screw 61.

Further, a supporter 90 and an insulator 80 are placed under the PCB 20 like those of FIG. 3. As shown in FIGS. 3 and 4, the supporter 90 is used to prevent the PCB 20 from being deformed due to the fastening of the screw 60. Therefore, if the PCB 20 is larger than a predetermined thickness or the IC package 10 is so small enough to free from the deformation owing to the pressure, there is no need of the supporter 90. Likewise, the insulator 80 is used for insulation between the supporter 90 and the PCB 20. Therefore, if the supporter 90 is not needed, there is also no need of the insulator 80.

In the IC holder of FIGS. 3 and 4 unlike that of FIG. 1, the guide panel 51, the insulating pad 52 and the case bodies 40-42, 40-52, 40-53, 40-54 and 40-55 are in direct contact with the PCB 20, so that the fastening of the screw 60 is further smoothly performed.

Although the present invention has been described with reference to certain exemplary embodiments thereof, it will be understood by those skilled in the art that a variety of modifications and variations may be made to the present invention without departing from the spirit or scope of the present invention defined in the appended claims, and their equivalents.

### INDUSTRIAL APPLICABILITY

Accordingly, an IC holder according to an exemplary embodiment of the present invention is capable of substituting for a socket because a case capable of holding an IC package is fastened and pressured to a PCB by a fastening unit such as a screw or the like such that an external connection terminal of the IC package is in direct contact with the PCB. Further, the IC package does not contact the PCB or otherwise is disposed to avoid neighboring devices or circuits, so that wiring of the PCB can be more freely designed.

Further, the IC holder contacts a large area of the IC package through a heat-dissipation unit such as a heat conductive tape or the like, thereby effectively dissipating heat. Also, devices can be readily replaced by solderless assembly, thereby solving environmental problems.

Also, an external connection terminal of the IC package is in direct contact with the PCB, so that the IC package can smoothly operate at high speed. Further, the IC package is covered with a metal holder, thereby preventing electromagnetic waves from radiating from the IC package.

Further, the IC holder can be used regardless of the kinds of IC packages such as BGA, PLCC, QFP type IC packages. Thus, the production cost is reduced. Also, the IC holder can be variously applied regardless of the number of external connection terminals of the IC package or the size of the IC package within an allowable limit.

1. An integrated circuit (IC) holder comprising:
a case into which an IC package is inserted;
a fastening unit for fastening the case to a printed circuit board (PCB);
a heat-dissipation unit for transferring heat from the IC package to the case; and
a guide panel allowing the external connection terminal of the IC package to precisely contact an electric pattern of the PCB by guiding an outer surface of the IC package.

2. The IC holder as claimed in claim 1, wherein the guide panel is made of an insulator which is in direct contact with the PCB, and designed to avoid devices disposed on the PCB.

3. The IC holder as claimed in claim 1, wherein the case comprises:
a case body into which the IC package is inserted; and
a caser cover fastened to an upper surface of the case body and pressing the IC package.

4. The IC holder as claimed in claim 3, wherein the case cover is designed as a heat sink for radiating heat from the IC package to the outside.

5. The IC holder as claimed in claim 1, wherein the case is made of metal and prevents electromagnetic waves generated from the IC package from radiating to the outside or prevents the IC package from malfunction due to external electromagnetic waves.

6. The IC holder as claimed in claim 1, wherein when the IC package comprises a lead as an external connection terminal, the IC holder further comprises a resilient insulator placed on a bottom of the case so that the lead of the IC package closely contacts the PCB.

7. The IC holder as claimed in claim 1, further comprising a guide pin to be inserted into a bottom of the case to decrease movement due to tolerance of the fastening unit.

8. The IC holder as claimed in claim 1, further comprising a heat sink placed on an upper surface of the case and radiating heat from the IC package to the outside.

9. The IC holder as claimed in claim 1, wherein the heat-dissipation unit has elasticity to make pressure applied from the fastening unit to a case be uniformly distributed to the IC package.

10. The IC holder as claimed in claim 1, further comprising:
a supporter placed under the PCB and preventing the PCB from deformation and damage; and
an insulator interposed between the PCB and the supporter.

11. The IC holder as claimed in claim 1, further comprising an electric conductive sheet that is placed between an external connection terminal of the IC package and the PCB and becomes conductive at a part where pressure is applied.

12. The IC holder as claimed in claim 11, wherein an outer surface of the electric conductive sheet is fastened by the guide panel.

13. An IC holder comprising:
four case bodies for fastening a corner of an IC package;
a first fastening unit for fastening the case bodies to a PCB;
a case cover placed on the case bodies and pressing the IC package to make an external connection terminal of the IC package contact an electric pattern of the PCB;
a heat-dissipation unit for transferring heat from the IC package to the case cover; and
a second fastening unit for fastening the case cover to the case bodies.

14. The IC holder as claimed in claim 13, wherein the case cover is designed as a heat sink to radiate heat generated from the IC package to the outside.

15. The IC holder as claimed in claim 13, wherein the case bodies are made of metal and prevents electromagnetic waves generated from the IC package from radiating to the outside or prevents the IC package from malfunction due to external electromagnetic waves.

16. The IC holder as claimed in claim 13, wherein the case cover is made of metal and prevents electromagnetic waves generated from the IC package from radiating to the outside or prevents the IC package from malfunction due to external electromagnetic waves.

17. The IC holder as claimed in claim 13, further comprising four insulating pads interposed between the PCB and the four case bodies, respectively, and being in direct contact with the PCB.

18. The IC holder as claimed in claim 13, further comprising a guide pin to be inserted into a bottom of the case bodies to decrease movement due to tolerance of the fastening unit.

19. The IC holder as claimed in claim 13, further comprising a heat sink placed on an upper surface of the case cover and radiating heat generated from the IC package to the outside.

20. The IC holder as claimed in claim 13, wherein the heat-dissipation unit has elasticity to make pressure applied from the fastening unit to the case cover be uniformly distributed to the IC package.

21. The IC holder as claimed in claim 13, further comprising:
a supporter placed under the PCB and preventing the PCB from deformation and damage; and
an insulator interposed between the PCB and the supporter.

22. The IC holder as claimed in claim 13, further comprising an electric conductive sheet that is placed between an external connection terminal of the IC package and the PCB and becomes conductive at a part where pressure is applied.

23. The IC holder as claimed in claim 22, wherein an outer surface of the electric conductive sheet is guided by the case bodies.
